(19) United States
(12) Patent Application Publication
(10) Pub. No.: US 2012/0299150 A1
(43) Pub. Date: Nov. 29, 2012

(54) Power Semiconductor Module with Embedded Chip Package

(75) Inventors: Benjamin Tang, Rancho Palos Verdes, CA (US); Laura Carpenter, Palos Verdes Estates, CA (US); Kenneth Ostrom, Palos Verdes Estates, CA (US); Frank Daeche, Unterhaching (DE)

(73) Assignees: PRIMARION, INC., Tempe, AZ (US); INFINEON TECHNOLOGIES AG, Neubiberg (DE)

(21) Appl. No.: 13/116,840

(22) Filed: May 26, 2011

(51) Int. Cl. H01L 27/04; H01L 21/60

(52) U.S. Cl. 257/531; 438/123; 257/E27.01; 257/E21.506

(57) ABSTRACT

A power semiconductor module includes a power semiconductor die, a metal substrate, a patterned metallization layer, a plurality of padless electrical connections, a plurality of vias and an inductor. The power semiconductor die has a top surface, an opposing bottom surface and a plurality of sides extending between the top and bottom surfaces. The metal substrate is attached to the bottom surface of the die. The patterned metallization layer is disposed above the top surface of the die. The plurality of padless electrical connections are at the top surface of the die and connect the patterned metallization layer to the die. The plurality of vias are disposed adjacent one or more of the sides of the die and electrically connected to the patterned metallization layer at a first end of the plurality of vias and to the metal substrate at a second end of the plurality of vias.

### FIELD OF TECHNOLOGY

The present application relates to power semiconductor modules, in particular power semiconductor modules with embedded chip packages.

### BACKGROUND

An integrated circuit (IC) for a voltage regulator typically includes one or more power switches housed in a package with patterned metallization layers above or below the IC die which provide interconnection to a printed circuit board (PCB) below the die. Additional passive, active and/or thermal components can be included in the package or attached to the PCB. For example, IC packaging solutions include QFN (Quad Flat No leads), BGA (Ball Grid Array), flip-chip on leadframe and chip embedded packaging of monolithic or module power stages.

In each case, the die typically has contact pads such as bond pads or solder ball pads which are designated surface areas of the die used to form electrical connections with metallization of the package. Electrical contact to the die pads can be made by soldering, wire bonding, flip-chip mounting or probe needles. However, voltage regulators usually require very high power transfer efficiency. The switches must therefore have very low (parasitic) resistance in the signal routing path. Contact pads on the die add to the overall path resistance, and therefore decrease power transfer efficiency.

Power transfer efficiency can be further increased by reducing the size of passive components of the regulator such as inductors and capacitors which in turn reduces the space and correspondingly the routing resistance. However, switching regulators tend to be relatively large because of a need for large components (inductors, ICs, discretes, capacitors, etc.) and also thermal requirements (heatsink, heat dissipation from PCB, etc.). Reducing the size of the components also requires use of high switching frequencies particularly in order to reduce the size of the inductors and capacitors, and good electrical performance and low parasitics are still desirable. Reducing the size of the overall package also presents thermal management challenges.

### SUMMARY

According to embodiments described herein, chip embedded packaging is used for integrated power supply components and modules to provide small switching regulator designs. Packaging solutions described herein allow the use of standard surface mount technology (SMT) inductors for small switching regulator designs. Optimized electrical and thermal designs of power supply components and modules are described herein using chip embedded package technology.

According to an embodiment of a power semiconductor module, the module includes a power semiconductor die, a metal substrate, a patterned metallization layer, a plurality of padless electrical connections and a plurality of vias. The power semiconductor die has a top surface, an opposing bottom surface and a plurality of sides extending between the top and bottom surfaces. The metal substrate is attached to the bottom surface of the die. The patterned metallization layer is disposed above the top surface of the die. The plurality of padless electrical connections are at the top surface of the die and connect the patterned metallization layer to the die. The plurality of vias are disposed adjacent one or more of the sides of the die and electrically connected to the patterned metallization layer at a first end of the plurality of vias and to the metal substrate at a second end of the plurality of vias. One or more passive, active and/or thermal components can be mounted above the patterned metallization layer so that the patterned metallization layer is interposed between the top surface of the die and the component(s) mounted above the patterned metallization layer.

According to another embodiment of a power semiconductor module, the module includes a semiconductor die, a metal substrate, a patterned metallization layer, a plurality of padless electrical connections and a plurality of vias. The semiconductor die includes an active region with one or more power transistors disposed above an inactive region devoid of transistors. The metal substrate is connected to the inactive region of the die. The patterned metallization layer is disposed above the die so that the active region of the die is interposed between the patterned metallization layer and the inactive region. The plurality of padless electrical connections are between the patterned metallization layer and the die. The plurality of vias are disposed laterally adjacent the die and electrically connected to the patterned metallization layer at a first end of the plurality of vias and to the metal substrate at a second end of the plurality of vias. One or more passive, active and/or thermal components can be mounted above the patterned metallization layer.

According to yet another embodiment of a power semiconductor module, the module includes a high side switch and a low side switch of a voltage converter, a lead frame, a patterned metallization layer, a first and second plurality of padless electrical connections, and a plurality of vias. The lead frame is connected to a first surface of the switches. The patterned metallization layer is disposed above a second surface of the switches, the first and second surfaces facing opposite directions. The first plurality of padless electrical connections are at the second surface of the high side switch and connect the patterned metallization layer to the high side switch. The second plurality of padless electrical connections are at the second surface of the low side switch and connect the patterned metallization layer to the low side switch. The plurality of vias laterally are spaced apart from the switches and electrically connected to the patterned metallization layer at a first end of the plurality of vias and to the lead frame at a second end of the plurality of vias. One or more passive, active and/or thermal components can be mounted above the patterned metallization layer so that the patterned metallization layer is interposed between the top surface of the die and the component(s) mounted above the patterned metallization layer.

According to an embodiment of a method of manufacturing a power semiconductor module, the method includes: connecting a metal substrate to a first surface of a power semiconductor die, the first surface being disposed closer to an inactive region of the die than an active region of the die; forming a plurality of padless electrical connections at a second surface of the die, the second surface being disposed closer to the active region of the die than the inactive region; disposing a patterned metallization layer above the second surface of the die and in electrical connection with the plurality of padless electrical connections; and forming a plurality of vias adjacent one or more of the sides of the die which are connected to the patterned metallization layer at a first end of the plurality of vias and to the metal substrate at a second end of the plurality of vias. One or more passive, active and/or thermal components can be mounted above the patterned metallization layer.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a side view of a power semiconductor module with an embedded chip package.

FIG. 2 illustrates a side view of a power semiconductor module with an embedded chip package and an inductor mounted to the embedded chip package.

FIG. 3 illustrates a plan view of a lead frame for use with a power semiconductor module having an embedded chip package and an inductor mounted to the embedded chip package.

FIG. 4 illustrates a circuit diagram of a buck converter included in a power semiconductor module having an embedded chip package and an inductor mounted to the embedded chip package.

FIG. 5 illustrates a schematic cross-sectional view of the power semiconductor module associated with FIG. 4 along the line labelled A-A′.

FIG. 6 illustrates a schematic cross-sectional view of the power semiconductor module associated with FIG. 4 along the line labelled B-B′.

FIG. 7 illustrates a side view of a power semiconductor module with an embedded chip package and an inductor mounted to the embedded chip package.

FIG. 8 illustrates a side view of a power semiconductor module with an embedded chip package and a heat sink mounted to the embedded chip package.

FIG. 9 illustrates a partial schematic cross-sectional view of a padless electrical connection to a power semiconductor die included in an embedded chip package.

FIGS. 10A-10B illustrate a method of forming the padless electrical connection shown in FIG. 9.

FIG. 11 illustrates a partial schematic cross-sectional view of a padless electrical connection to a power semiconductor die included in an embedded chip package.

FIGS. 12A-12E illustrate a method of manufacturing of a power semiconductor module with an embedded chip package.

### DETAILED DESCRIPTION

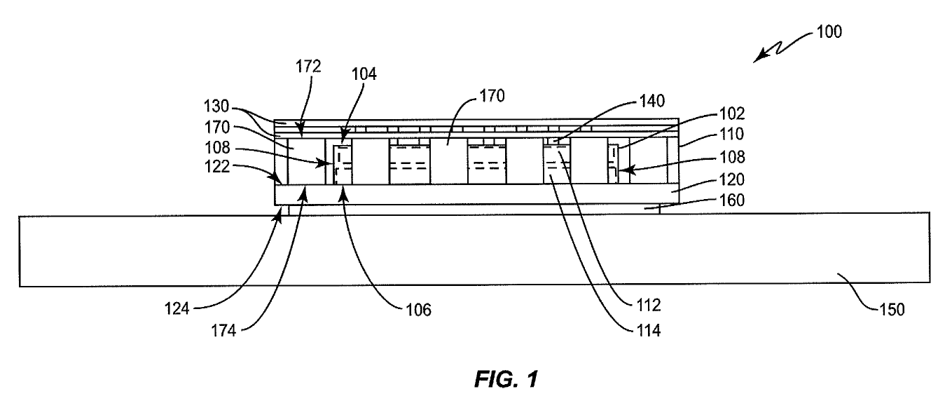

FIG. 1 illustrates a side view of an embodiment of a power semiconductor module 100. The module 100 includes a power semiconductor die 102 embedded in a package 110. The die 102 has a top surface 104, an opposing bottom surface 106 and a plurality of sides 108 extending between the top and bottom surfaces 104, 106. The die 102 includes an active region 112 with one or more power transistors disposed above an inactive region 114 which is devoid of transistors. For example, the inactive region 114 may be a bulk section of a semiconductor substrate such as a Si wafer and the active region 112 may be an epitaxial layer grown on the substrate and/or a region of the substrate implanted with donor (n-type) and/or acceptor (p-type) atoms. The module 100 further includes a metal substrate 120 having a top surface 122 attached to the bottom surface 106 of the die 102, one or more patterned metallization layers 130 disposed above the top surface 104 of the die 102 and a plurality of padless electrical connections 140 at the top surface 104 of the die 102 which connect the patterned metallization layer(s) 130 to the die 102. These connections 140 at the top surface 104 of the die 102 are padless in that the die 102 does not have contact pads such as bond pads or solder ball pads at the top surface 104 of the die 102. Instead, these electrical connections 140 directly contact an uppermost metal layer of the die 102 or a liner on the uppermost metal layer as described in more detail later herein. This way, the resistance of the routing (wiring) path is reduced by not using die contact pads.

A printed circuit board (PCB) 150 can be attached to the bottom surface 124 of the metal substrate 120 so that the metal substrate 120 is interposed between the bottom surface 106 of the die 102 and the PCB 150. The PCB 150 can be attached to the metal substrate 120 using a solder, epoxy or other suitable joining layer or layers 160. The metal substrate-solder-PCB interface provides a good thermal path.

The power semiconductor module 100 also includes a plurality of vias 170 disposed adjacent one or more of the sides 108 of the die 102. That is, the vias 170 are positioned around the periphery of the die 102. The vias 170 are electrically connected to the patterned metallization layer(s) 130 at a first end 172 of the vias 170 and to the metal substrate 120 at a second opposing end 174 of the vias 170. Electrical connections between the die 102 and the PCB 150 are provided through the metal substrate 120, vias 170, patterned metallization layer(s) 130 and padless electrical connections 140 at the top surface 104 of the die 102. The current flow path has a first (mostly) horizontal component traversing the metal substrate 120, a first (mostly) vertical component traversing the vias 170, a second (mostly) horizontal component traversing the patterned metallization layer(s) 130, a second (mostly) vertical component traversing the padless electrical connections 140. The module 100 thus has a die-up package configuration in that the active side of the die 102, including doped semiconductor layers and metallization, faces toward the patterned metallization layer(s) 130 and away from PCB 150 after mounting on the metal substrate 120. The doped semiconductor layers and metallization of the die 102 provide high density interconnectivity independent of the PCB footprint. As such, the PCB footprint can be independently designed from the uppermost metallization pattern of the die 102.

One or more passive, active and/or thermal components e.g. such as capacitor(s), inductor(s), resistor(s), heatsink(s), etc. can be mounted above the patterned metallization layer so that the patterned metallization layer is interposed between the top surface of the die and the component(s) mounted above the patterned metallization layer.

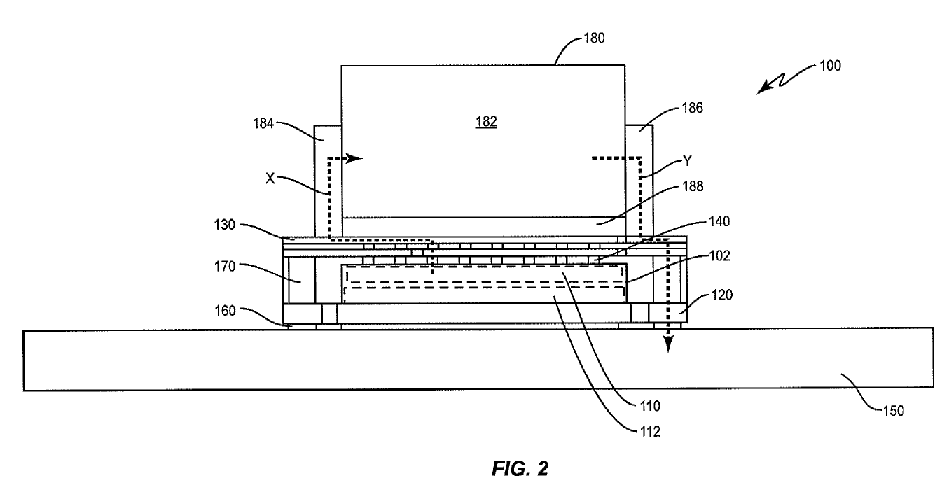

FIG. 2 shows the power semiconductor module 100 with an inductor 180 mounted above the patterned metallization layer(s) 130 according to an embodiment. The patterned metallization layer(s) 130 are interposed between the top surface 104 of the die 102 and the inductor 180. The inductor 180 is mounted above the patterned metallization layer(s) 130 and not directly on the PCB 150, reducing the size requirement of the PCB 150, providing a good electrical interface with the inductor 180, and increasing the thermal mass and conduction to airflow. The embedded package 110 which includes the die 102 is disposed between the PCB 150 and the inductor 180. According to one embodiment, the inductor 170 is a surface mount (SMT) inductor with a body 182 and terminals 184, 186 connected to the patterned metallization layer(s) 130. An air gap 188 can be provided between the uppermost patterned metallization layer 130 and the surface mount inductor 180.

The current flow path between the inductor 180 and the die 102 (e.g. from a power stage toward the inductor) can include one or more of the patterned metallization layer(s) 130 and one or more of the padless electrical connections 140 at the top surface 104 of the die 102 as indicated by the dashed line labelled ‘X’ in FIG. 2, and exclude the PCB 150 and vias 170. The current flow path between the inductor 180 and the PCB 150 (e.g. from the inductor toward the output or load) can include one or more of the patterned metallization layer(s) 130, one or more of the vias 170 and the metal substrate 120 as indicated by the dashed line labelled ‘Y’ in FIG. 2, and exclude the plurality of padless electrical connections 140 and die 102.

In one embodiment, the inductor 180 has an inductance ranging from 10 nH to 10 uH and a size ranging from 2 mm×2 mm×2 mm to 20 mm×20 mm×20 mm. The switching frequency (Fsw) of the power stage can be 300 KHz to 30 MHz. The XY dimensions of the embedded package 110 which includes the die 102 can be slightly larger or smaller than that of the inductor 180. The thickness of the embedded package 110 can range from 100 um to 2 mm and the die 102 may have up to 200 um clearance at the edge of the embedded package 110.

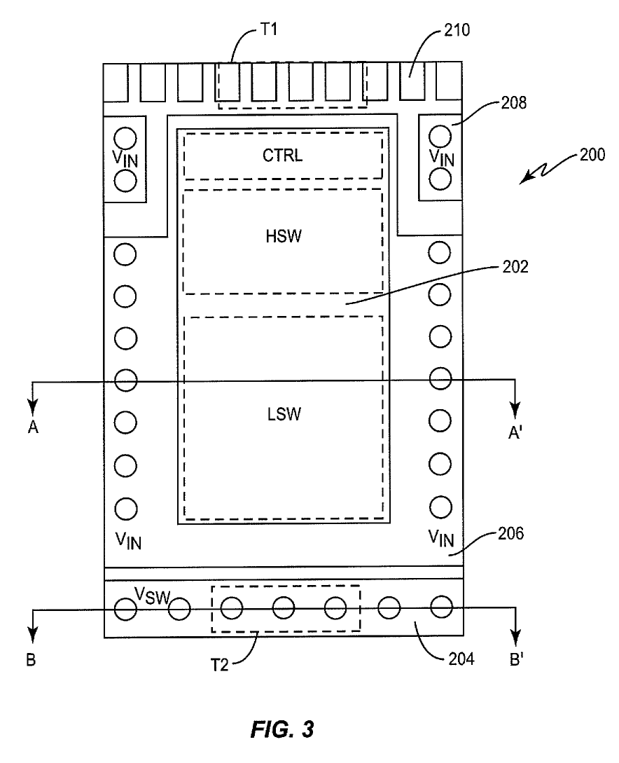

FIG. 3 shows a plan view of an embodiment of the metal substrate 120. The metal substrate 120 is a lead frame 200 according to this embodiment. The lead frame 200 has a central region 202 and leads 204, 206, 208, 210 which extend laterally outward from the central region 202. The die 102 is attached to the central region 202, and the vias 170 are electrically connected to the leads 204, 206, 208, 210 at the second 174 end of the vias 170. A first terminal 184 of the inductor 180 is electrically connected to a first lead 210 of the lead frame 200 (indicated by the dashed box labelled ‘T1’ in FIG. 3), through a first section of the patterned metallization layer(s) 130 and one or more of the plurality of vias 170 electrically connected to this section. The other terminal 186 of the inductor 180 is electrically connected to a second lead 204 of the lead frame 200 (indicated by the dashed box labelled ‘T2’ in FIG. 3), through a second section of the patterned metallization layer(s) 130 different than the first section and one or more of the plurality of vias 170 electrically connected to the second section.

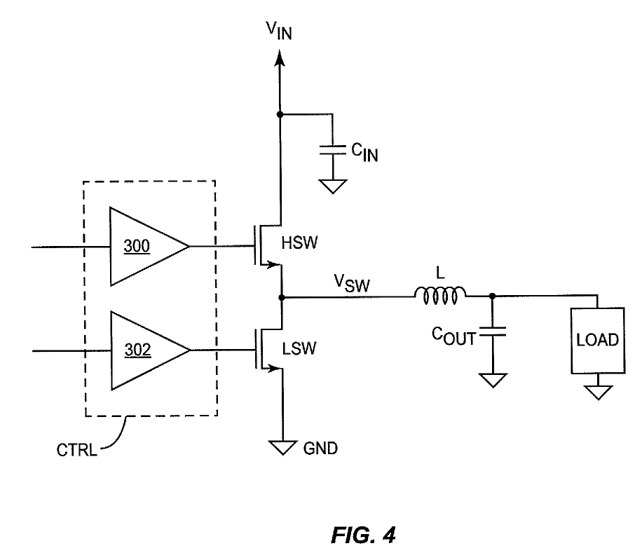

FIG. 4 shows an embodiment of the power semiconductor device housed in the module 100. The power semiconductor device is a buck converter according to this embodiment, but other types of voltage converters or power devices may be included in the module 100. The buck converter includes a voltage input (Vin), an input capacitor (Cin), a high side switch (HSW) such as a high side FET (field effect transistor), a low side switch (LSW) such as a low side FET, a control stage (CTRL) including a driver 300, 302 for each switch, an inductor (L) having a first terminal coupled to the switched output (Vsw) of the device and a second terminal coupled to an output capacitor (Cout), and a load. The output voltage (Vout) applied to the load is a function of the duty cycle of the high side and low side switches as is well known in the art. Accordingly, no further explanation of the buck converter operation is given. The electrical connections (e.g. Vin, Vsw) to the leads 204, 206, 208, 210 of the lead frame 200 and the mechanical connections (HSW, LSW, CTRL) to the central region 202 of the lead frame 200 are respectively indicated with dashed boxes in FIG. 3.

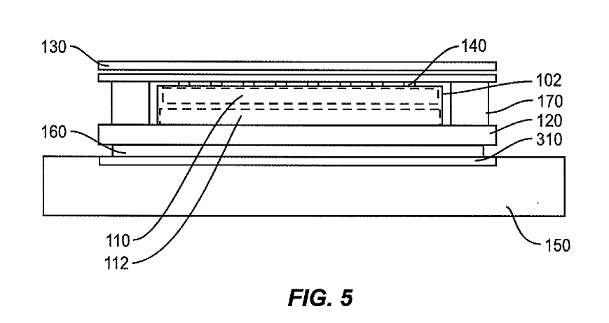

FIG. 5 illustrates a schematic cross-sectional view of the power semiconductor module 100 without the inductor 180, along the line labelled A-A′ in FIG. 3. FIG. 5 shows the electrical path from the input voltage (Vin) to the source of the high side switch (HSW) includes a first region (leads) of the lead frame 200, the vias 170 electrically connected to the first region of the lead frame 200, a first section of the patterned metallization layer(s) 130 and one or more of the padless electrical connections 140 connected to the first section of the patterned metallization layer(s) 130. The low side switch (LSW) is electrically connected to ground. The footprint of the PCB 150 can be designed for good thermal conduction, and may include a large ground (GND) clump, via, plane etc. 310 for increasing the thermal conductivity of the ground path.

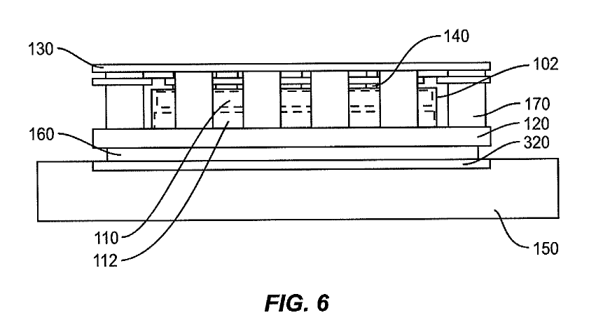

FIG. 6 illustrates a schematic cross-sectional view of the power semiconductor module 100 again without the inductor 180, along the line labelled B-B′ in FIG. 3. FIG. 6 shows the electrical path from the switched voltage output (Vsw) of the device to a second region (leads) of the lead frame 200. The path includes the vias 170 electrically connected to the second region of the lead frame 200, a second section of the patterned metallization layer(s) 130 and one or more of the padless electrical connections 140 connected to the second section of the patterned metallization layer(s) 130. Again, the footprint of the PCB 150 can be designed for good thermal conduction and may include another large clump, via, plane etc. 320 for increasing the thermal conductivity of the switching voltage (Vsw) path.

The active region 110 of the die 102 can include both the high side switch and the low side switch of the power stage. That is, the high side and low side switches can be integrated on the same die 102. The die 102 can also have passive integrated devices such as one or more capacitors, inductors and/or resistors, or a network of such passive devices.

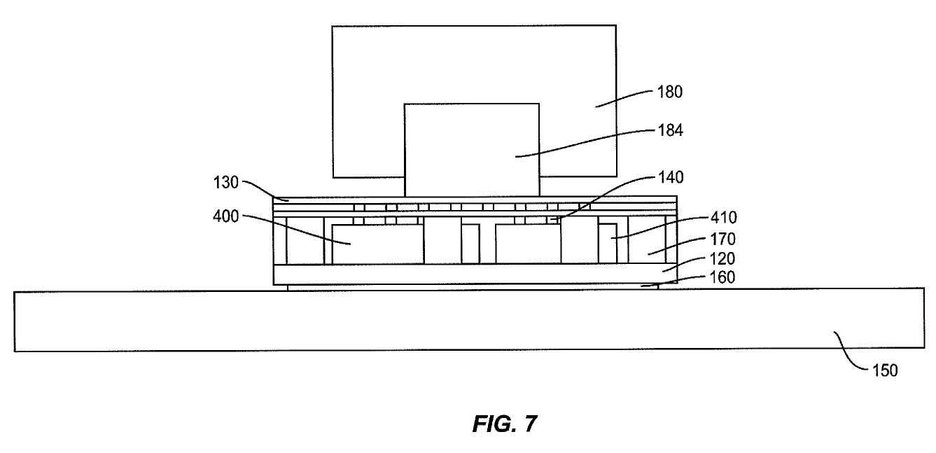

FIG. 7 illustrates a side view of another embodiment of the power semiconductor module 100. According to this embodiment, the power stage is implemented with separate discrete die. A first die 400 has an active region which includes a high side switch of the power stage. A second die 410 has an active region which includes a low side transistor of the power stage. The inactive region of both die is devoid of transistors and disposed below the active region so that the inactive regions are disposed closer to the metal substrate 120 than the active regions, respectively. The metal substrate 120 is connected to the inactive region of both die 400, 410. The active region of each die 400, 410 is interposed between the patterned metallization layer(s) 130 and the respective inactive region. Padless electrical connections 140 are provided at the top surface of both die 400, 410 to provide electrical connections which extend between the patterned metallization layer(s) 130 and the die 400, 410. The vias 170 are disposed laterally adjacent the die 400, 410 and electrically connect the patterned metallization layer(s) 130 and the metal substrate 120 as previously described herein.

In an alternate embodiment, the transistors of the power stage can be integrated in the same die 400 as described previously herein. The additional die 410 interposed between the patterned metallization layer(s) 130 and the metal substrate 120 as shown in FIG. 7 can include one or more passive devices. For example, the additional die 410 can include one or more capacitors, inductors, and/or resistors or networks constructed from such components.

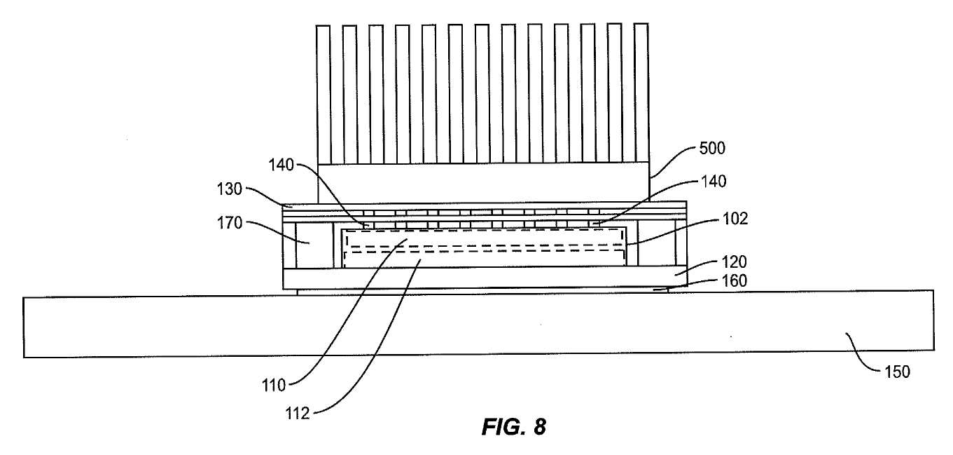

FIG. 8 illustrates a side view of another embodiment of the power semiconductor module 100. According to this embodiment, a heat sink 500 is mounted above the patterned metallization layer(s) 130. This way, the patterned metallization layer(s) 130 are interposed between the top surface 104 of the die 102 and the heat sink 500. The uppermost patterned metallization layer 130 can be solid or mostly solid to increase thermal mass and thermal conductivity between the heat sink 500 and the die 102. The sensitive control portion (CTRL) of the power stage can be located under the solid/mostly solid uppermost patterned metallization layer 130 to provide shielding. The metal substrate 120 can also be solid or mostly solid to increase thermal mass and thermal conductivity between the die 102 and the PCB 150. One or more additional passive, active and/or thermal components can be mounted above the patterned metallization layer(s) 130 so that the patterned metallization layer(s) are interposed between the top surface 104 of the die 102 and the component(s) mounted above the patterned metallization layer(s) 130. For example, the inductor 180 shown in FIGS. 2 and 7 can also be mounted above the patterned metallization layer(s) 130 as previously described herein.

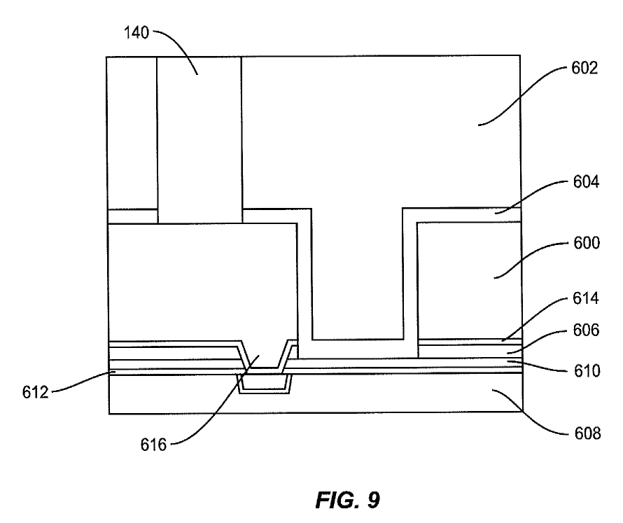

FIG. 9 illustrates a schematic cross-sectional view of part of the die metallization above the active region 110 of the die 102 according to an embodiment. The die 102 has an uppermost metal layer 600 above the active region 110 which is out of view in FIG. 9, and an insulating layer 602 such as polyimide above the uppermost metal layer 600. In one embodiment, the uppermost metal layer 600 comprises copper and is 5 um or less thick. A nitride layer 604 can be formed between the uppermost metal layer 600 and the polyimide 602, and along the sides of the uppermost metal layer 600. A passivation layer 606 such as nitride can be formed between the uppermost metal layer 600 and the next lower metal layer 608. One or more additional insulating layers 610, 612 can also be provided between the uppermost metal layer 600 and the next lower metal layer 608. A padless electrical connection 140 extends between the patterned metallization layer(s) 130 which are out of view in FIG. 9 and the uppermost metal layer 600 through openings in the insulating layer 602. This way, the padless electrical connection 140 directly contacts the uppermost metal layer 600 according to this embodiment. In the case of copper wiring, a copper seed layer 614 is also present. Vias 616 extend between vertically adjacent metal layers to form vertical electrical connections within the die metallization, providing signal paths from the active region 110 of the die 102 to the uppermost metal layer 600.

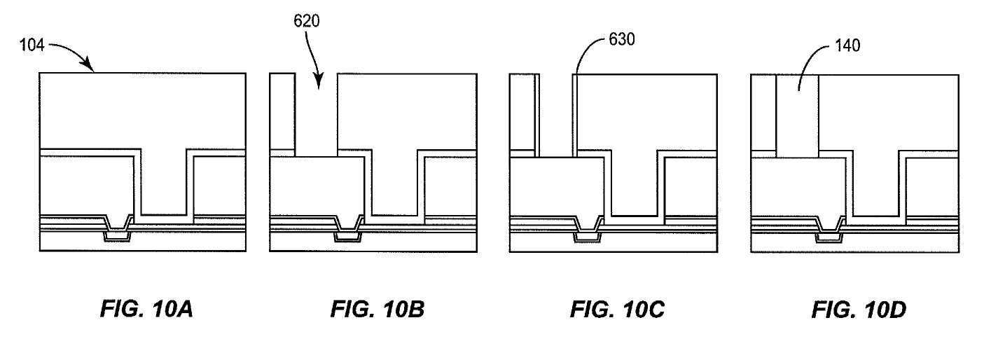

FIGS. 10A-10D illustrate an embodiment of forming a padless electrical connection 140 at the top surface 104 of the die 102. According to this embodiment, the embedded package construction has no openings formed in the uppermost insulating layer 602 or other protective passivation layer 604 disposed above the uppermost metal layer 600 prior to formation of the padless electrical connection 140 as shown in FIG. 10A. Openings 620 are then formed in the uppermost insulating layer 602 and any intervening passivation layer 604 so that certain regions of the uppermost metal layer 600 are exposed as shown in FIG. 10B. Laser drilling through the uppermost insulating layer(s) 602, 604 is used in one embodiment to form the openings 620. For copper wiring, a seed layer 630 is formed on the exposed sidewalls of the uppermost insulating layer(s) 602, 604 as shown in FIG. 10C. The seed layer deposition step can be skipped for aluminium wiring. The padless electrical connection 140 is then formed in each opening 620 in the insulating layer(s) 602, 604 e.g. by metal deposition (e.g. for Al wiring) or electroplating (e.g. for Cu wiring) so that the padless electrical connection 140 directly contacts the uppermost metal layer 600. This construction eliminates the conventional pad opening and formation steps and protects the uppermost metal layer 600 during the subsequent die to package fabrication step, allowing for more reliable high current interface between the die 102 and package 110.

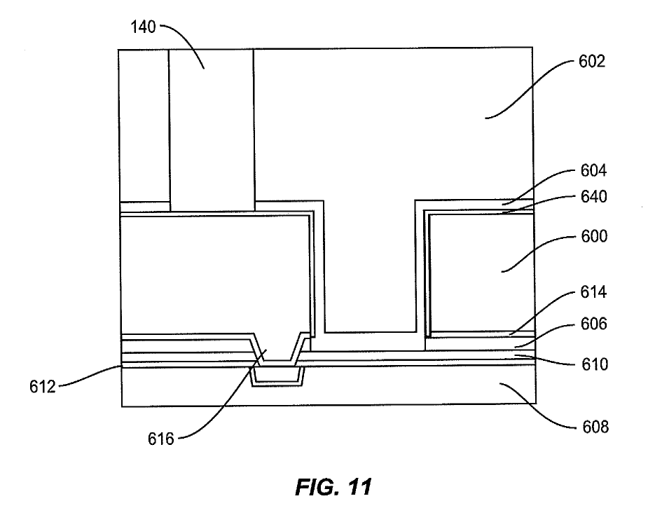

FIG. 11 illustrates a schematic cross-sectional view of part of the die metallization above the active region 110 of the die 102 according to another embodiment. A liner 640 such as a Cu Si liner is formed on the top and sides of the uppermost metal layer 600 according to this embodiment. The same process steps described above with regard to FIGS. 10A-10D for forming the padless electrical connection 140 can be used here, except the openings 620 formed in the uppermost insulating layer 602 and any intervening passivation layer 604 stop at the liner 640 instead of the uppermost metal layer 600. Again, these connections 140 at the top surface 104 of the die 102 are padless in that the die 102 does not have contact pads such as bond pads or solder ball pads at the top surface 104 of the die 102. Instead, the padless electrical connections 140 directly contact the liner 640 formed on the uppermost metal layer 600.

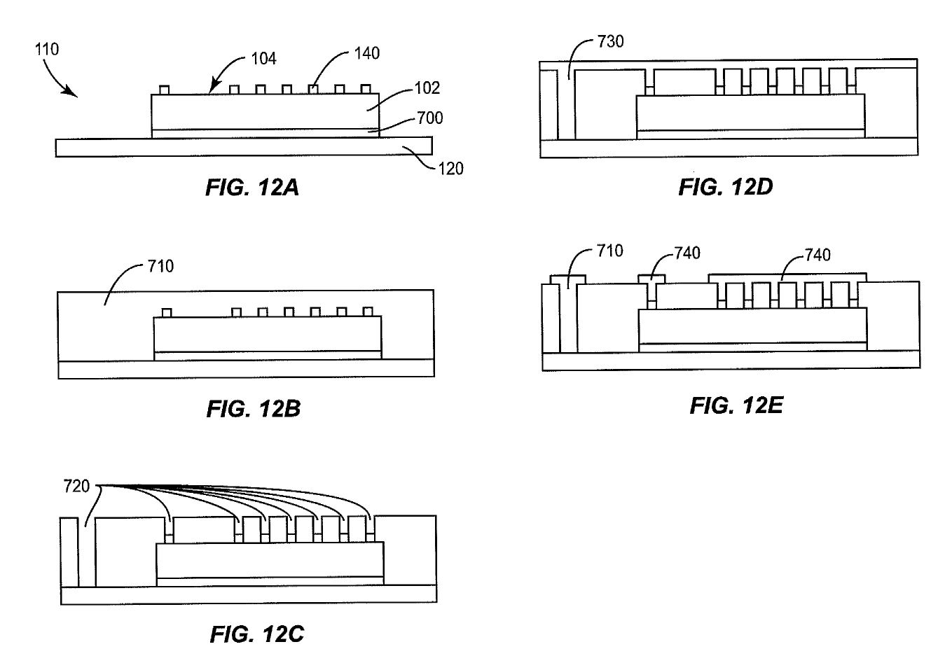

FIGS. 12A-10E illustrate an embodiment of attaching the die 102 to the metal substrate 102 to form the embedded package 110, and forming the padless electrical connections 140 at the top surface 104 of the die 102. The embedded package 110, which includes the die 102, is attached to the metal substrate 120 e.g. via solder or epoxy 700 as shown in FIG. 12A. A film 710 such as RRC (resin coated copper) or prepreg (pre-impregnated composite fibers) is then laminated over the embedded package 110 as shown in FIG. 12B. FIG. 12C shows openings 720 formed in the laminated film 710 at the top surface 104 of the die 102 for forming the padless electrical connections 140 as previously described herein and at edge regions of the metal substrate 120 where the die 102 is not present for forming openings for the vias 170 which extend between the metal substrate 120 and the overlying patterned metallization layer(s) 130 which is to be subsequently formed. In one embodiment, the openings 720 in the laminated film 710 are formed by laser drilling. Metal 730 is then deposited (e.g. for Al wiring) or electroplated (e.g. for Cu wiring) over the laminated film 710 to fill the openings 720 as shown in FIG. 12D. The metal 730 is structured e.g. by etching to form the vias 710 at laterally adjacent the sides of the die 102 and the padless electrical connections 140 at the top surface 104 of the die 102 as shown in FIG. 12E. Alternatively, a mask can be used to deposit or electroplate the structured metal which forms the vias 170 and padless electrical connections 140. In each case, padless electrical connections 140 coupled to the same node (e.g. Vin or Vsw) can be electrically connected or contiguous as shown in FIG. 12E.

The patterned metallization layer(s) 130 are then formed on the embedded package 110. One or more passive, active and/or thermal components such as inductor 180 and/or heatsink 500 can be mounted above the patterned metallization layer(s) 130 as previously described herein. The PCB 150 is then attached to the bottom of the metal substrate 120. As such, there can be two different temperature processes after the embedded package 110 is fabricated: the component-to-embedded package attach process and the PCB-to-metal substrate attach process. In one embodiment, the inductor 180 is attached to the uppermost patterned metallization layer 130 using a relatively high melting point solder followed by a standard reflow process for attaching the PCB 150 to the metal substrate 120 using a lower melting point solder. This way, the solder used to attach the inductor 180 does not reflow during the subsequent PCB attach process. In another embodiment, a high melting point solder alloy such as CuSn is used to attach the inductor 180 to the uppermost patterned metallization layer 130 so that the inductor 180 remains joined to the embedded package 110 during the subsequent PCB attach process. In yet another embodiment, the inductor 180 is glued to the uppermost patterned metallization layer 130 and a standard reflow process is subsequently employed for permanently attaching the inductor 180 to the uppermost patterned metallization layer 130 and the PCB 150 to the metal substrate 120. In each case, multiple die can be processed at the same time at the wafer level or diced and then assembled.

Spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power semiconductor module, comprising:
a power semiconductor die having a top surface, an opposing bottom surface and a plurality of sides extending between the top and bottom surfaces;
a metal substrate attached to the bottom surface of the die;
a patterned metallization layer disposed above the top surface of the die;
a plurality of padless electrical connections at the top surface of the die which connect the patterned metallization layer to the die; and
a plurality of vias disposed adjacent one or more of the sides of the die and electrically connected to the patterned metallization layer at a first end of the plurality of vias and to the metal substrate at a second end of the plurality of vias.

2. The power semiconductor module of claim 1, wherein the metal substrate is a lead frame comprising a central region and leads which extend laterally outward from the central region, the die is attached to the central region, and the plurality of vias are electrically connected to the leads at the second end of the plurality of vias.

3. The power semiconductor module of claim 1, further comprising an inductor mounted above the patterned metallization layer so that the patterned metallization layer and the die are interposed between the inductor and the metal substrate.

4. The power semiconductor module of claim 3, wherein a first terminal of the inductor is electrically connected to a first lead of the lead frame through a first section of the patterned metallization layer and one or more of the plurality of vias electrically connected to the first section, and a second terminal of the inductor is electrically connected to a second lead of the lead frame through a second section of the patterned metallization layer different than the first section and one or more of the plurality of vias electrically connected to the second section.

5. The power semiconductor module of claim 3, further comprising a printed circuit board below the metal substrate so that the metal substrate is interposed between the bottom surface of the die and the printed circuit board.

6. The power semiconductor module of claim 5, wherein a current flow path between the inductor and the die includes the patterned metallization layer and one or more of the plurality of padless electrical connections, and excludes the printed circuit board and the plurality of vias.

7. The power semiconductor module of claim 5, wherein a current flow path between the inductor and the printed circuit board includes the patterned metallization layer, one or more of the plurality of vias and the metal substrate, and excludes the plurality of padless electrical connections and the die.

8. The power semiconductor module of claim 3, wherein the inductor is a surface mount inductor electrically connected to the patterned metallization layer.

9. The power semiconductor module of claim 1, further comprising an additional semiconductor die interposed between the patterned metallization layer and the metal substrate, the additional semiconductor die comprising one or more passive devices.

10. The power semiconductor module of claim 1, wherein the die comprises an uppermost metal layer above an active region and an insulating layer above the uppermost metal layer, and wherein the plurality of padless electrical connections extend between the patterned metallization layer and the uppermost metal layer through openings in the insulating layer so that the padless electrical connections directly contact the uppermost metal layer or a liner on the uppermost metal layer.

11. The power semiconductor module of claim 1, further comprising a heat sink mounted above the patterned metallization layer so that the patterned metallization layer is interposed between the top surface of the die and the heat sink.

12. A power semiconductor module, comprising:
a semiconductor die including an active region with one or more power transistors disposed above an inactive region devoid of transistors;
a metal substrate connected to the inactive region of the die;
a patterned metallization layer disposed above the die so that the active region of the die is interposed between the patterned metallization layer and the inactive region;
a plurality of padless electrical connections between the patterned metallization layer and the die; and
a plurality of vias disposed laterally adjacent the die and electrically connected to the patterned metallization layer at a first end of the plurality of vias and to the metal substrate at a second end of the plurality of vias.

13. The power semiconductor module of claim 12, wherein the active region of the die includes a high side switch of a power stage and a low side switch of the power stage.

14. The power semiconductor module of claim 13, wherein the high side switch is electrically connected to an input voltage through a first region of the metal substrate, one or more of the plurality of vias electrically connected to the first region, a first section of the patterned metallization layer and one or more of the plurality of padless electrical connections connected to the first section, and the low side switch is electrically connected to ground.

15. The power semiconductor module of claim 12, wherein the die comprises an uppermost metal layer above the active device region and an insulating layer above the uppermost metal layer, and wherein the plurality of padless electrical connections extend between the patterned metallization layer and the uppermost metal layer through openings in the insulating layer so that the padless electrical connections directly contact the uppermost metal layer or a liner on the uppermost metal layer.

16. The power semiconductor module of claim 12, wherein the active region of the die includes a high side switch of a power stage, and wherein the power semiconductor module further comprises an additional semiconductor die comprising an active region which includes a low side switch of the power stage above an inactive region devoid of transistors.

17. The power semiconductor module of claim 16, wherein the metal substrate is connected to the inactive region of the additional die, the active region of the additional die is interposed between the patterned metallization layer and the inactive region of the additional die, another plurality of padless electrical connections extend between the patterned metallization layer and the additional die, and another plurality of vias are disposed laterally adjacent the additional die and electrically connected to the patterned metallization layer.

18. The power semiconductor module of claim 12, further comprising an inductor mounted above the patterned metallization layer so that the inductor is disposed closer to the active region of the die than the inactive region.

19. A power semiconductor module, comprising:
a high side switch of a voltage converter;
a low side switch of the voltage converter;
a lead frame connected to a first surface of the switches;
a patterned metallization layer disposed above a second surface of the switches, the first and second surfaces facing opposite directions;
a first plurality of padless electrical connections at the second surface of the high side switch which connect the patterned metallization layer to the high side switch;
a second plurality of padless electrical connections at the second surface of the low side switch which connect the patterned metallization layer to the low side switch; and
a plurality of vias laterally spaced apart from the switches and electrically connected to the patterned metallization layer at a first end of the plurality of vias and to the lead frame at a second end of the plurality of vias.

20. The power semiconductor module of claim 19, wherein the switches are integrated on the same semiconductor die.

21. The power semiconductor module of claim 19, further comprising an inductor mounted above the patterned metallization layer so that the patterned metallization layer is interposed between the inductor and the second surface of the switches.

22. The power semiconductor module of claim 21, wherein the inductor is a surface mount inductor and an air gap is disposed between the second surface of at least one of the switches and the surface mount inductor.

23. A method of manufacturing a power semiconductor module, comprising:
connecting a metal substrate to a first surface of a power semiconductor die, the first surface being disposed closer to an inactive region of the die than an active region of the die;
forming a plurality of padless electrical connections at a second surface of the die, the second surface being disposed closer to the active region of the die than the inactive region;
disposing a patterned metallization layer above the second surface of the die and in electrical connection with the plurality of padless electrical connections; and
forming a plurality of vias adjacent one or more of the sides of the die which are connected to the patterned metallization layer at a first end of the plurality of vias and to the metal substrate at a second end of the plurality of vias.

24. The method of claim 23, wherein the metal substrate is a lead frame having a central region and leads which extend laterally outward from the central region, the method comprising:
attaching the die to the central region; and
connecting the plurality of vias to the leads at the second end of the plurality of vias.

25. The method of claim 23, further comprising mounting an inductor above the patterned metallization layer so that the patterned metallization layer is interposed between the second surface of the die and the inductor.

26. The method of claim 25, wherein mounting the inductor above the patterned metallization layer comprises:
electrically connecting a first terminal of the inductor to a first lead of the lead frame through a first section of the patterned metallization layer and one or more of the plurality of vias electrically connected to the first section; and
electrically connecting a second terminal of the inductor to a second lead of the lead frame through a second section of the patterned metallization layer different than the first section and one or more of the plurality of vias electrically connected to the second section.

27. The method of claim 23, further comprising attaching a printed circuit board to a surface of the metal substrate which faces away from the die so that the metal substrate is interposed between the bottom surface of the die and the printed circuit board.

28. The method of claim 23, further comprising interposing an additional semiconductor die between the patterned metallization layer and the metal substrate, the additional semiconductor die comprising one or more passive devices.

29. The method of claim 23, wherein the die comprises an uppermost metal layer above an active region and an insulating layer above the uppermost metal layer, and wherein forming the plurality of padless electrical connections at the second surface of the die comprises:
forming openings in the insulating layer which expose the uppermost metal layer or a liner on the uppermost metal layer; and
forming the plurality of padless electrical connections in the openings formed in the insulating layer so that the padless electrical connections directly contact the uppermost metal layer or a liner on the uppermost metal layer.
